(19) United States
(12) Patent Application Publication
(10) Pub. No.: US 2012/0313481 A1
(43) Pub. Date: Dec. 13, 2012

(54) Electroactive Polymer Generator for Converting Mechanical Energy into Electrical Energy

(75) Inventors: Benjamin Hagemann, Gerlingen (DE); Ulrich Fass, Trierweiler (DE); Siegbert Steinlechner, Leonberg (DE); Dieter Schwarzmann, Heilbronn (DE); Tobias Herrmann, Aschaffenburg (DE); Ioan Serban, Ludwigsburg (DE)

(73) Assignee: Robert Bosch GmbH, Stuttgart (DE)

(21) Appl. No.: 13/516,633

(22) PCT Filed: Oct. 27, 2010
(86) PCT No.: PCT/EP2010/006549

§ 371 Date: Aug. 24, 2012

(30) Foreign Application Priority Data
Dec. 18, 2009 (DE) 10 2009 058 984.8

(51) Int. Cl. H01L 41/113; F03B 13/16

(52) U.S. Cl. 310/311

(57) ABSTRACT

An electroactive polymer generator is configured to convert mechanical energy into electrical energy during expansion and compression of the polymer generator. The polymer generator comprises a device for detecting expansion and compression states. The device comprises at least one acceleration sensor.

The invention relates to an electroactive polymer generator for converting mechanical energy into electrical energy on stretching and contraction of the polymer generator. The polymer generator comprises a device for detecting stretching and contraction states.

Document WO 2007/130252 A2 describes a generator system, in which electroactive polymers are used to convert wave motion into electrical energy. Since for electrical activation of the electroactive polymer to proceed cooperation is required between an instantaneous stretching state of the polymer generator and a control device of the polymer generator, document US 2007/0257490 A1 uses a position sensor to determine the position of the electroactive polymer, by means of which activation of the polymer generator is controlled with the assistance of the control device.

Position determination purely with a position sensor has the disadvantage that only movements which relate to a single degree of freedom are taken into account.

It is the object of the invention to provide an electroactive polymer generator in which alternative methods and sensors are used to detect stretching states and contraction states of the polymer generator and to contribute to control of the polymer generator.

This object is achieved with independent claim 1. Advantageous further developments of the invention are revealed by the dependent claims.

The invention provides an electroactive polymer generator for converting mechanical energy into electrical energy on stretching and contraction of the polymer generator. The polymer generator comprises a device for detecting stretching and/or contraction states. The device comprises at least one acceleration sensor.

This solution is associated with the advantage that detection of the stretching and contraction states of the electroactive polymer generator proceeds with the assistance of at least one acceleration sensor, which is associated with greater precision of detection for stretching and contraction states, so meaning improved efficiency of energy conversion is achieved, especially since improved control of the electroactive polymer generator is then possible. Acceleration may be converted by integration into a speed and by further integration ultimately into a determined position and is not restricted to one direction of movement. In this way, complex multi-dimensional movement patterns may also be detected and stretching states monitored, if a larger installation consisting of a plurality of mechanically interconnected electroactive polymer generators is designed.

The individual electroactive polymer generator comprises a dielectric elastomer and electrodes consisting of a flexible electrically conductive material, which follows stretching and contraction of the elastomer. Conduction of generated charges away from the elastomer is reliably ensured by way of appropriately flexible electrodes, which are capable of following the deformations, stretching and contraction of the electroactive polymer generator.

In one embodiment of the invention, the acceleration sensor signals a maximum value on reversal of the stretching of the polymer generator, wherein in this state of largely maximum stretching of the electroactive polymer generator a maximum voltage is achieved.

Provision is additionally made for the device for detecting stretching and contraction states to comprise a three-dimensional acceleration sensor. In this way, stretching and contraction states may be detected three-dimensionally and the efficiency of the polymer generator optimized. Using a plurality of acceleration sensors, it is additionally possible to detect, monitor and control complex multi-dimensional movement patterns and stretching states of mechanically coupled electroactive polymer generators and to optimize them for the purposes of converting mechanical energy into electrical energy. A three-dimensional acceleration sensor allows the detection of multi-dimensional relative movements and still better monitoring of a stretching state of the electroactive polymer generator and improved activation of the generator.

One use for electroactive polymer generators is in a wave power installation. In this case the electroactive polymer generator or capacitor is typically mounted between at least two end pieces. If these end pieces change their relative position, this leads to a change in the stretching state in the electroactive polymer generator. This change may be used to produce energy, if a maximum amount of electrical charge can be applied to the electrodes of the electroactive polymer generator in the state of largely maximum stretching, i.e. large capacitance with large surface area and small spacing, and can be conducted away in an energy-producing manner in the state of largely maximum relaxation. These two states may be reliably and accurately detected with the acceleration sensor, since they are typically reversal points, at which stretching or contraction reaches a maximum.

If multi-dimensional relative movements are passed through between moving portions of a generator installation with a plurality of polymer generators, if for example a wave power installation comprises a plurality of independently activated electroactive polymer generators, an acceleration sensor may be mounted in each moving portion of such an installation, with which sensor the relative movement of the mutually independently activated electroactive polymer generators relative to one another may be determined and thus activation may be optimally designed for each individual electroactive polymer generator.

In one embodiment of the invention, on reversal of the stretching direction the control device transmits charges from the electroactive polymer to a buffer storage means, wherein the buffer storage means is a charging capacitor.

Moreover, the acceleration sensor advantageously signals to the control unit on reversal of stretching of the electroactive polymer generator into a mechanical relaxation phase, such that the generator circuit may respond thereto.

A wave power installation with electroactive polymer generators may be arranged as a wave follower in a swell. The polymer generators may comprise a common generator circuit with a rechargeable battery, a buffer storage means and a control device. Depending on the swell and the accelerations at the polymer generators caused by the swell, the control device transmits charges to the buffer storage means and/or charges the rechargeable battery and/or feeds a load.

The invention will now be explained in greater detail with reference to the attached figures.

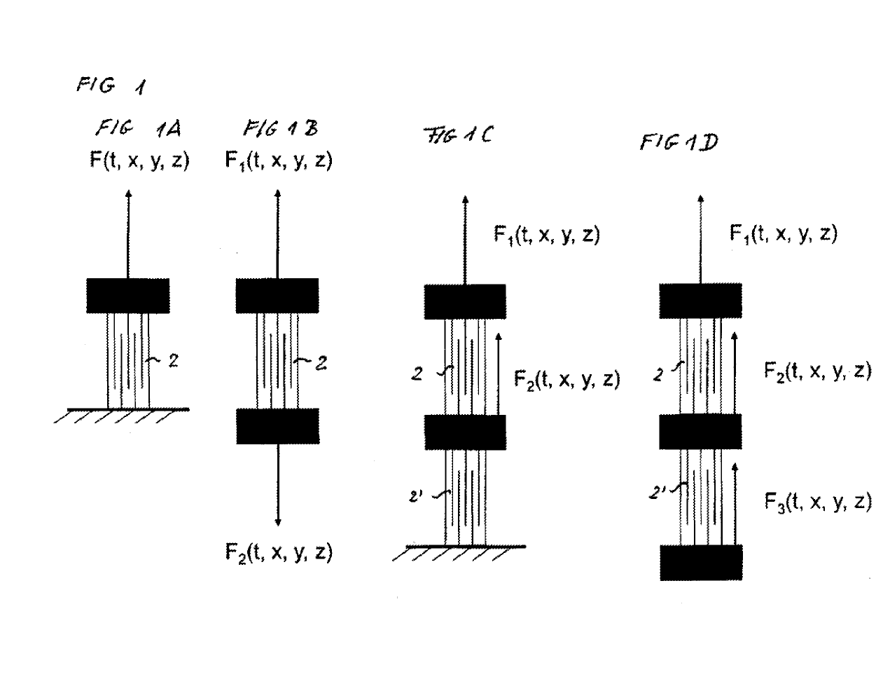

FIG. 1 shows in FIGS. 1A to 1D options for time- and location-dependent application of force to mounted polymer generators;

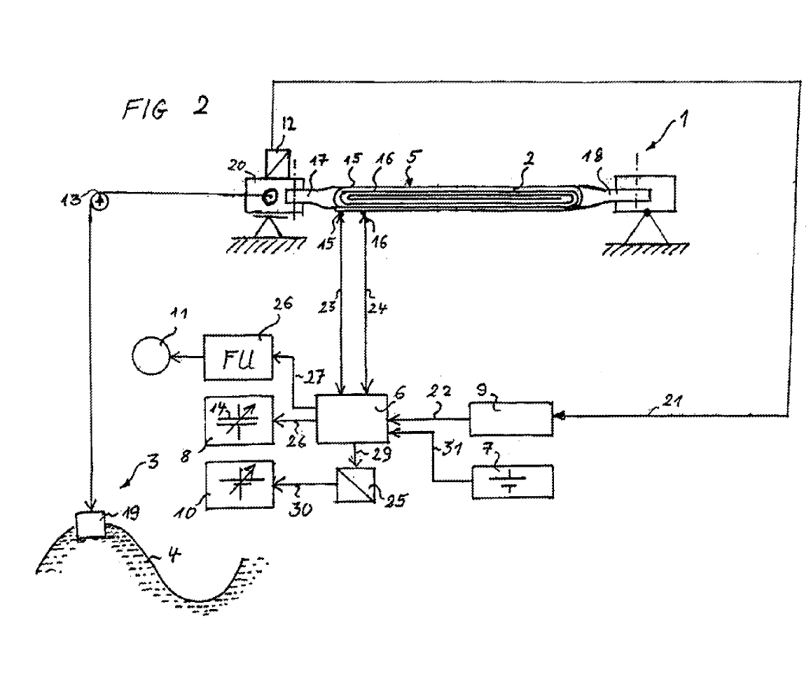

FIG. 2 shows a possible use for an electroactive polymer generator in a wave power installation.

In FIGS. 1A to 1D, FIG. 1 shows options for time- and location-dependent application of force F(t,x,y,z) on mounted polymer generators 2. To this end, the polymer generator 2 in FIG. 1A is fixed at one end and a force F₁(t,x,y,z) stretches or contracts the polymer generator 2, wherein the stretching or contraction state is detected by means of an acceleration sensor mounted on the black end piece.

In FIG. 1B, the polymer generator 2 is secured at both ends to moving parts, such that the stretching or contraction states brought about by opposing directed forces F₁(t,x,y,z) and F₂(t,x,y,z) may be detected by means of two acceleration sensors.

If, as in FIG. 1C, two electroactive polymer generators 2 and 2′ are arranged in series one behind the other relative to a fixed end, stretching or contraction states of the two electroactive polymer generators caused by the forces F₁(t,x,y,z) and F₂(t,x,y,z) may be detected by two acceleration sensors.

If the electroactive polymer generators 2 and 2′ shown in FIG. 1D are mounted in series one behind the other on moving parts, stretching or contraction states of the two electroactive polymer generators 2 and 2′ caused by the active forces F₁(t,x,y,z), F₂(t,x,y,z) and F₃(t,x,y,z) may be detected by three acceleration sensors.

FIGS. 1A to 1D show quadruple capacitors by way of example, but these are not intended to be limiting.

FIG. 2 shows a possible use of an electroactive polymer generator 2 in a wave power installation 1. In this embodiment of the wave power installation said electroactive polymer generator 2 is wound up into a flat capacitor 5. To this end, an electroactive elastomer film tape is coated on one side with an electrode 15 and a counter-electrode 16, which oppose one another in the case of suitably structured electrodes and a suitable winding method and form a variable capacitance due to the electroactive elastomer arranged therebetween.

Through one-sided application of the electrode 15 and counter-electrode 16 the flat, wound-up capacitor 5 with electroactive elastomer may be straightforwardly contacted. The flexible electroactive polymer generator of electrode, counter-electrode and electroactive elastomer is reinforced at its edges 17 and 18 and mounted in a holder, wherein an acceleration sensor 12 is arranged at the edge 18, which sensor detects the accelerated movements of the flexible electroactive polymer 2 and thus accurately and reliably determines the stretching and contraction states.

These movements are caused by a swell 4, in which a float 19 is arranged, forming a wave follower 3, whose movements are transmitted by a deflecting element 13 and a coupling element 20 to the flexible electroactive polymer generator 2. When the flexible electroactive polymer generator 2 is subjected to a load, the electroactive elastomer film is stretched. An acceleration sensor 12 is used up on the coupling element 20, which records the movements of the polymer generator 2. These accelerations are signaled via a signal line 21 to a control device 9.

The control device 9 is connected to a generator circuit 6 by way of a control line 22, wherein the generator circuit 6 additionally charges and discharges the electrodes 15 and 16 via leads 23 and 24. Furthermore, in a start phase of the capacitor a supply battery 7, which is connected to the generator circuit via a supply line 31, ensures an initial field strength in the electroactive polymer generator 2. Via a connecting line 29 and a DC/DC converter 25, the generator circuit 6 may feed the charges produced to a rechargeable battery 10 via a further connecting line 30. Alternatively it is also possible to store the charges produced on a charging capacitor 14 of a buffer storage means 8 via an outgoing lead 26.

Provision is additionally made for the generator circuit to be connected electrically to a frequency converter 26 via an electrical line 27. The frequency converter transforms the relatively low frequency of the swell 4 into the corresponding line frequency of the load, in order to feed the electrical energy produced from the mechanical wave energy to a distribution grid. The acceleration sensor 12, the control device 9 and the generator circuit 6 of this wave power installation 1 may be arranged in the float 19.

Since such a wave follower 3 converts the wave energy into electrical energy in the wave power installation 1 at individual sea level positions, a plurality of such wave followers 3 are assembled in the wave power installation 1, wherein each wave follower 3, also known as a “point absorber”, is coupled to an electroactive polymer generator 2. The polymer generators 2 are equipped with appropriate acceleration sensors 12, which detect the movements in order to collect the electrical energy produced with the assistance of the electroactive polymer generator 2 and make it usable by the load 11.

In addition to linearly accelerated changes of movement, the acceleration sensor 12 may also detect multi-dimensional relative movements such as for example accelerated rotational and wobbling changes of movement of a wave power installation 1.

### LIST OF REFERENCE NUMERALS

1 Wave power installation
2 Electroactive polymer generator
3 Wave follower
4 Swell
5 Capacitor
6 Generator circuit
7 Supply battery
8 Buffer storage means
9 Control device
10 Rechargeable battery
11 Load
12 Acceleration sensor
13 Deflecting element
14 Charging capacitor
15 Electrode
16 Counter-electrode
17 Edge
18 Edge
19 Float
20 Coupling element
21 Signal line
22 Control line
23 Lead
24 Lead
25 DC/DC converter
26 Frequency converter
27 Connecting line
29 Connecting line
30 Connecting line
31 Supply line

1. An electroactive polymer generator comprising:
a device configured to detect stretching and/or contraction states, the device including at least one acceleration sensor,
wherein the electroactive polymer generator is configured to convert mechanical energy into electrical energy in response to stretching and contraction of the polymer generator.

2. The electroactive polymer generator as claimed in claim 1, further comprising:
a dielectric elastomer and electrodes of a flexible electrically conductive material, configured to follow the stretching and contraction of the elastomer.

3. The electroactive polymer generator as claimed in claim 2, wherein:
the acceleration sensor signals a maximum value on reversal of the stretching of the electroactive polymer generator, and
in this largely maximum stretching state the generated electrical voltage at the electrodes of the electroactive polymer reaches a maximum value.

4. The electroactive polymer generator as claimed in claim 1, wherein the device for detecting stretching and/or contraction states comprises at least one three-dimensional acceleration sensor.

5. An electroactive polymer generator installation, comprising:
a plurality of acceleration sensors configured to detect and monitor complex multi-dimensional movement patterns and stretching states of mechanically coupled electroactive polymer generators.

6. A wave power installation, comprising:
a plurality of electroactive polymer generators, each electroactive polymer generator of the plurality of electroactive polymer generators including a device configured to detect stretching and/or contraction states, each of the devices having at least one acceleration sensor,
wherein the plurality of electroactive polymer generators is configured to convert mechanical energy into electrical energy in response to stretching and contraction of at least one electroactive polymer generator of the plurality of electroactive polymer generators.

7. The wave power installation as claimed in claim 6, wherein:
the wave power installation is arranged as a wave follower in a swell and the plurality of electroactive polymer generators forms a capacitor with variable capacitance,
a generator circuit comprises a supply battery or a buffer storage means and a control device, and
the control device, depending on the stretching and contraction states of the plurality of polymer generators detected by at least one of the acceleration sensors, charges or discharges the capacitor, and transmits electrical charges to the buffer storage means and/or charges a rechargeable battery and/or feeds a load.

8. The wave power installation as claimed in claim 6, wherein in addition to linear accelerated changes of movement, the acceleration sensors also detect multi-dimensional relative movements such as accelerated rotational and wobbling changes of movement of the wave power installation.

9. The wave power installation as claimed in claim 7, wherein:
each electroactive polymer generator of the plurality of electroactive polymer generators includes a dielectric elastomer and electrodes of a flexible electrically conductive material configured to follow the stretching and contraction of the elastomer,
on reversal of the stretching direction, the control device transmits charges from the electroactive polymer generator to the buffer storage means, and
the buffer storage means is a charging capacitor.
